(19) United States
(12) Patent Application Publication
(10) Pub. No.: US 2025/0254793 A1
(43) Pub. Date: Aug. 7, 2025

(54) SYSTEMS, METHODS, STORAGE MEDIUM FOR INKJET-PRINTED GEL-ELECTRONIC

(71) Applicant: THE REGENTS OF THE UNIVERSITY OF COLORADO, A BODY CORPORATE, Denver, CO (US)

(72) Inventors: Eloise BIHAR, Boulder, CO (US); Gregory L. WHITING, Boulder, CO (US); Elliot J. STRAND, Boulder, CO (US)

(21) Appl. No.: 18/855,837

(22) PCT Filed: Apr. 11, 2023
(86) PCT No.: PCT/US2023/018150

§ 371 Date: Oct. 10, 2024

Related U.S. Application Data
(60) Provisional application No. 63/330,187, filed on Apr. 12, 2022.

(51) Int. Cl. H05K 1/11; C09D 11/30; C09D 11/52; H05K 3/12

(52) U.S. Cl. CPC H05K 1/11; C09D 11/30; C09D 11/52; H05K 3/125

(57) ABSTRACT

A method for fabricating a printed gel-electronic circuit includes depositing a conductive material on a substrate, depositing first gel over the conductive material on the substrate, air-drying the first gel, depositing second gel over the air-dried gel, freezing a combination of the second gel, the air-dried gel, and the conductive material, and thawing the combination of the second gel, the air-dried gel, and the conductive material.

### CROSS REFERENCES TO RELATED APPLICATIONS

This application claims benefits of Provisional Application No. 63/330,187, entitled “Inkjet-Printed Gel-Electronics for Biosensing and Electrostimulation,” filed Apr. 12, 2022, of which entire content is incorporated by reference herein.

### GOVERNMENT RIGHTS

This invention was made with government support under grant number 1935594 awarded by the National Science Foundation. The government has certain rights in the invention.

### FIELD

This disclosure relates to systems, methods, and storage media generally for inkjet-printed gel-electronic, and more particularly for fabricating inkjet-printed gel-electronic via a freeze-thaw process for biosensing and electrostimulation.

### BACKGROUND

Significant technological advances over the past decade have enabled the development of miniaturized, ultra-thin electronics that can be integrated into new platforms such as e-skin, tattoo-like sensors, or implantable transient electronics for treating, monitoring, or diagnosing health conditions. More recently, such devices have been investigated for monitoring plant physiological parameters for precision farming, which is critical to the agricultural industry, and for monitoring of environmental conditions.

Soft electronics have also been gaining a great deal of interest as they have the potential to be applied to many biomedical fields (soft robotics, neuromorphic, biosensing, and others). Lately, there has been an emphasis on developing approaches that offer new pathways to soft electronics. Patterning of the conducting traces and other required materials typically relies on conventional techniques such as photolithography or approaches like blade coating that have limited patterning capability. Recently, conducting polymer has been used as the conducting trace in countless printed flexible electronic devices for biomedical applications as well as for agricultural applications. So far, patterning electronic devices in hydrogels to directly interface with biological tissues remains a challenge as most conducting inks require sintering processes and high temperatures to boost their electronic properties, which is typically incompatible with hydrogels.

### BRIEF SUMMARY

Disclosed embodiments include security systems, methods, apparatuses, and storage media for fabricating inkjet-printed gel-electronic via freeze-thaw processing and utilizing the inkjet-printed gel-electronic for biosensing and electrostimulation. By using bio-compatible gel, stable and implantable gel-based bioelectronic devices can be formed and show stable long-term operation inside biological objects (e.g., tissue, plant, etc.).

This summary is provided to introduce a selection of concepts in a simplified form that are further described below in the Detailed Description. Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims or may be learned by the practice of the invention as set forth hereinafter.

In accordance with embodiments of the present disclosure, a method for fabricating a printed gel-electronic circuit includes depositing a conductive material on a substrate, depositing first gel over the conductive material on the substrate, air-drying the first gel, depositing second gel over the air-dried gel, freezing a combination of the second gel, the air-dried gel, and the conductive material, and thawing the combination of the second gel, the air-dried gel, and the conductive material.

In various aspects, the conductive material is ejected through a nozzle of inkjet printer.

In various aspects, freezing and thawing steps are performed more than one time.

In various aspects, the second gel is deposited over a portion of the air-dried first gel.

In various aspects, the conductive material forms an electrode, a capacitor, a transistor, or any combination thereof.

In various aspects, a width of each trace of the conductive material is greater than or equal to 100 micrometers.

In various aspects, the first gel is hydrogel.

In various aspects, the second gel is cryogel.

In various aspects, the first gel and the second gel are biocompatible and made of polyvinyl alcohol (PVA), Poly(2-hydroxyethyl methacrylate) (PHEMA), Polyacrylamide (PAAm), Polyethylene glycol diacrylate (PEGDA), Sodium alginate, Polyvinyl alcohol (PVA), Polyethylene oxide (PEO), Polyvinylpyrrolidone (PVP), Methacrylic acid (MAA), N-isopropylacrylamide (NIPAAm), Poly(ethylene glycol) methacrylate (PEGMA), Hydroxypropyl methylcellulose (HPMC), Polyethylene glycol (PEG), Gelatin, Carboxymethyl cellulose (CMC), Chitosan, Sodium hyaluronate (HA), Polyacrylic acid (PAA), Poly(2-hydroxypropyl methacrylate) (PHPMA), Polysaccharide-based hydrogels, Poly(ethylene oxide)-poly(propylene oxide) poly(ethylene oxide) triblock copolymers (PEO-PPO-PEO), Poly(ethylene glycol) dimethacrylate (PEGDMA), Poly(N-vinyl-2-pyrrolidone) (PNVP), Poly(vinyl alcohol-co-vinyl acetate) (PVA-VAc), Poly(methacrylic acid-co-ethylene glycol dimethacrylate) (PMAA-EGDMA), Poly(ethylene oxide-co-2-(diethylamino)ethyl methacrylate) (PEO-DEAEMA), Sodium polyacrylate, Poly(acrylic acid co 2 hydroxyethyl methacrylate) (PAA-HEMA), Agarose, Poly(N isopropylacrylamide-co-acrylic acid) (NIPAAm-AAc), and/or Poly(acrylamide co-2-acrylamido-2-methylpropanesulfonic acid) (PAM-AMPS).

In various aspects, the freezing the combination is performed at a temperature less than or equal to −20° C. and for at least 30 minutes.

In accordance with embodiments of the present disclosure, a gel-electronic circuit fabricated by a freeze-thaw process, the gel-electronic circuit includes an electronic circuit, which has been formed by a conductive material and includes at least two terminals, a first gel covering the electronic circuit and being air-dried, and a second gel covering the first gel and being freeze-thawed.

In various aspects, the gel-electronic circuit is stretchable, and the gel-electronic circuit has a self-healing property based on hydroxyl groups in the first and second gels.

In various aspects, the second gel is deposited over a portion of the air-dried first gel.

In various aspects, the electronic circuit includes an electrode, a capacitor, a transistor, or any combination thereof.

In various aspects, a transconductance of the transistor is in a milli-Siemens range, and a capacitance of the capacitor is less than or equal to 4.2 millifarad.

In various aspects, a width of each trace of the electronic circuit is greater than or equal to 100 micrometers.

In various aspects, a conductivity of each trace is less than or equal to 350 Siemens/cm.

In various aspects, the first gel and the second gel are biocompatible and made of polyvinyl alcohol (PVA), Poly(2-hydroxyethyl methacrylate) (PHEMA), Polyacrylamide (PAAm), Polyethylene glycol diacrylate (PEGDA), Sodium alginate, Polyvinyl alcohol (PVA), Polyethylene oxide (PEO), Polyvinylpyrrolidone (PVP), Methacrylic acid (MAA), N-isopropylacrylamide (NIPAAm), Poly(ethylene glycol) methacrylate (PEGMA), Hydroxypropyl methylcellulose (HPMC), Polyethylene glycol (PEG), Gelatin, Carboxymethyl cellulose (CMC), Chitosan, Sodium hyaluronate (HA), Polyacrylic acid (PAA), Poly(2-hydroxypropyl methacrylate) (PHPMA), Polysaccharide-based hydrogels, Poly(ethylene oxide)-poly(propylene oxide) poly(ethylene oxide) triblock copolymers (PEO-PPO-PEO), Poly(ethylene glycol) dimethacrylate (PEGDMA), Poly(N-vinyl-2-pyrrolidone) (PNVP), Poly(vinyl alcohol-co-vinyl acetate) (PVA-VAc), Poly(methacrylic acid-co-ethylene glycol dimethacrylate) (PMAA-EGDMA), Poly(ethylene oxide-co-2-(diethylamino)ethyl methacrylate) (PEO-DEAEMA), Sodium polyacrylate, Poly(acrylic acid co 2 hydroxyethyl methacrylate) (PAA-HEMA), Agarose, Poly(N isopropylacrylamide-co-acrylic acid) (NIPAAm-AAc), and/or Poly(acrylamide co-2-acrylamido-2-methylpropanesulfonic acid) (PAM-AMPS).

In accordance with embodiments of the present disclosure, a method is for monitoring an electrochemical status of an object by using a gel-electronic circuit fabricated by a freeze thaw process. The method includes implanting electrodes of the gel-electronic circuit into a portion of an object, monitoring electrical signals from the gel-electronic circuit for a period of time based on ion movements through the object, and determining an electrochemical status of the object by comparing the monitored electrical signals with a plurality of predetermined signal profiles.

In various aspects, the period is greater than or equal to 120 days without corroding the electrodes.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings described below.

FIG. 1 depicts a graphical process of fabricating gel-electronic circuit in accordance with embodiments of the present disclosure;

FIG. 2A depicts curves showing charging and discharging patterns of an air-dried gel-capacitor in accordance with embodiments of the present disclosure;

FIG. 2B depicts curves showing charging and discharging patterns of a freeze-thawed gel-capacitor in accordance with embodiments of the present disclosure;

FIG. 2C depicts curves of showing charging and discharging patterns of air-dried and freeze-thawed gel-capacitors in accordance with embodiments of the present disclosure;

FIG. 3A depicts stress curves based on repetition numbers of freeze-thaw processes in accordance with embodiments of the present disclosure;

FIG. 3B depicts stress curves based on durations of the freeze-thaw process in accordance with embodiments of the present disclosure;

FIG. 4A depicts data plots of drain current of an organic electrochemical transistor, which is air-dried, in accordance with embodiments of the present disclosure;

FIG. 4B depicts data plots of drain current of an organic electrochemical transistor, which is air-dried with ionic gel, in accordance with embodiments of the present disclosure;

FIG. 4C depicts data plots of drain current of an organic electrochemical transistor, which is freeze-thawed with ionic gel, in accordance with embodiments of the present disclosure;

FIG. 5 depicts graphical illustration of a system for monitoring a grow status of a plant with an implanted gel-electronic circuit in accordance with embodiments of the present disclosure;

FIG. 6A depicts Nyquist plots of gel-electronic implanted in a plant in accordance with embodiments of the present disclosure;

FIG. 6B depicts bar graphs of electrochemical impedance measured by a gel-electronic circuit implanted in a plant in accordance with embodiments of the present disclosure;

FIG. 7 depicts a flowchart of fabricating gel-electronic circuit in accordance with embodiments of the present disclosure;

FIG. 8 depicts a flowchart of monitoring a growth status of a plant by implanted gel-electronic in accordance with embodiments of the present disclosure; and

FIG. 9 depicts a block diagram of a computing device in accordance with embodiments of the present disclosure.

### DETAILED DESCRIPTION

Disclosed embodiments include systems, methods, and storage media for fabricating gel-electronic circuit and monitoring a growth status of a plant by the gel-electronic circuit. The gels can be customized to provide various electronic functionalities, including electrodes and organic electrochemical transistors (OECT). These gel-based devices exhibit high electrical conductivity for embedded conductive polymer traces, high transconductance for OECTs, and high capacitance in capacitive structures. These devices also show high stretchability strain, and self-healing properties. The biocompatible functionalized gel-based electrodes and transistors may be implanted in plant tissue. Ionic activity in plants may be collected for a period of time with minimal scar tissue formation over the period. These gel-based electronic devices exhibit good candidates for continuous, in-situ monitoring environmental status and health of a biological object including plants.

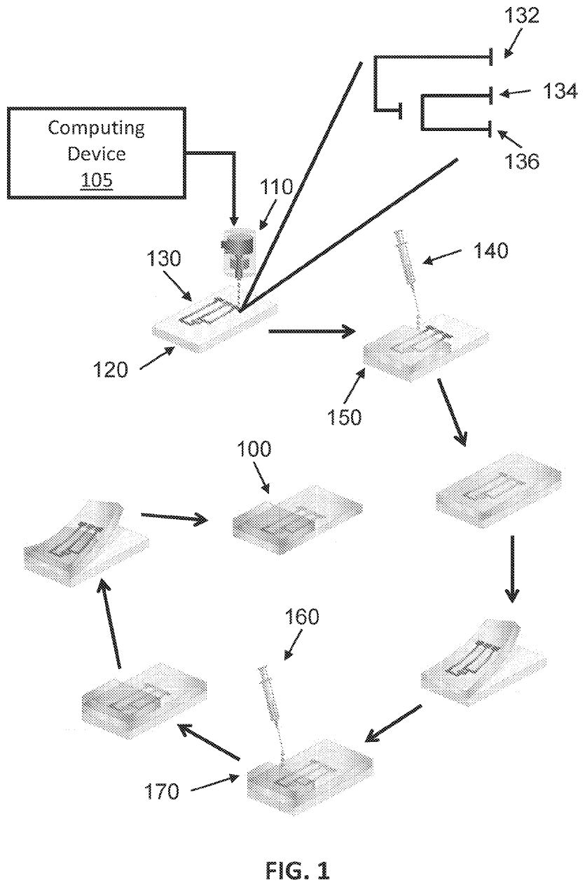

FIG. 1 graphically illustrates how to fabricate one or more gel-electronic circuits in accordance with embodiments of the present disclosure. The gel-electronic circuit 100 may include an electronic circuit 130, a first gel covering 150, and a second gel covering 170. The electronic circuit 130 may be a combination of conductive traces. Based on geographical relationships among the conductive traces, the electronic circuit 130 may be a resistor, capacitor, inductor, transistor, operational amplifier, or any other electrical component.

For example, the electronic circuit 130, as shown in the expanded view on the top right corner of FIG. 1, is a transistor, which has three terminals. Two terminals 134 and 136 function as drain and source terminals, and one terminal 132 acts as a gate terminal.

The electronic circuit 130 may be designed previously via a computing device 105 by a circuit designer. The computing device 105 may be a specific purpose computer dedicated for designing electronic circuits or may have an electronic circuit design program installed thereon. The circuit design may include a width and a length of each trace of the electronic circuit 130, components of the traces, and geographical relationships of the traces in a two-dimensional space.

After completion of the circuit design, the computing device 105 may be caused by the circuit designer to instruct or request a printer to print the electronic circuit 130 on a substrate 120. In response to the request, an inkjet head 110 of the printer prints the electronic circuit 130 on the substrate 120 by ejecting or depositing a conductive material, which forms conductive traces. The substrate 120 may be glass, ceramic, or any other substrate, from which the electronic circuit 130 can be easily peeled off.

The conductive material may include conductive polymer composite comprising citric acid and cyclodextrin, polyvinyl alcohol (PVA) covalently crosslinked by glutaraldehyde (GA), and conducting polymer (e.g., Poly(3,4-ethylenedioxythiophene)-poly(styrenesulfonate) (PEDOT:PSS)) to fabricate self-adhesive films for electromyography. PEDOT:PSS may be in aqueous inks whose rheological properties are compatible with low-cost printing processes (such as inkjet and screen printing). This conductive polymer may be used as conductive traces in countless printed flexible electronic devices for biomedical applications as well as for agricultural applications. In an aspect, the conducting polymer may be successively cured on a conventional hot plate at 90° C. under ambient conditions.

In an aspect, the conductive material may be electrochromic so that, when charged or discharged in a capacitor circuit, the color of the capacitor changes. Thus, a charging and discharging status can be easily identified by simply looking at a change in color. PEDOT:PSS is one of such conductive materials.

In another aspect, the width of the conductive trace may be greater than or equal to 100 μm. The width of the conductive trace may also be dependent upon the resolution of the inkjet head 110. The electronic circuit 130 may include one or more electronic circuit elements (e.g., resistors, inductors, capacitors, transistors, etc.) to form a complicated electronic circuit.

After completion of depositing the electronic circuit 130, first gel may be deposited to cover the electronic circuit 130. The gel may be drop-casted by a syringe 140 with a needle. Alternatively, the inkjet head 110 may be also utilized to deposit the first gel according to the circuit design for the gel-electronic circuit 100. The first gel may be hydrogel, which is made of PVA, Poly(2-hydroxyethyl methacrylate) (PHEMA), Polyacrylamide (PAAm), Polyethylene glycol diacrylate (PEGDA), Sodium alginate, Polyvinyl alcohol (PVA), Polyethylene oxide (PEO), Polyvinylpyrrolidone (PVP), Methacrylic acid (MAA), N-isopropylacrylamide (NIPAAm), Poly(ethylene glycol) methacrylate (PEGMA), Hydroxypropyl methylcellulose (HPMC), Polyethylene glycol (PEG), Gelatin, Carboxymethyl cellulose (CMC), Chitosan, Sodium hyaluronate (HA), Polyacrylic acid (PAA), Poly(2-hydroxypropyl methacrylate) (PHPMA), Polysaccharide-based hydrogels, Poly(ethylene oxide)-poly(propylene oxide)-poly(ethylene oxide) triblock copolymers (PEO-PPO-PEO), Poly(ethylene glycol) dimethacrylate (PEGDMA), Poly(N-vinyl-2-pyrrolidone) (PNVP), Poly(vinyl alcohol-co-vinyl acetate) (PVA-VAc), Poly(methacrylic acid-co-ethylene glycol dimethacrylate) (PMAA-EGDMA), Poly(ethylene oxide-co-2-(diethylamino)ethyl methacrylate) (PEO-DEAEMA), Sodium polyacrylate, Poly(acrylic acid-co-2-hydroxyethyl methacrylate) (PAA-HEMA), Agarose, Poly(N-isopropylacrylamide-co-acrylic acid) (NIPAAm-AAc), and/or Poly(acrylamide-co-2-acrylamido-2-methylpropanesulfonic acid) (PAM-AMPS). This list of chemical compounds is provided as examples and may include other chemical compounds for the hydrogel. In an aspect, PVA-based gels may be prepared by dissolving different ratios between deionized water and PVA weight, for example, 100:5, 100:10, or 100:20. The PVA may have different molecular weights, for example, 31,000-50,000, 89,000-98,000, or 146,000-186,000. The PVA powder may be dissolved in deionized water at 90° C. using magnetic stirring to create the hydrogels or the first gel 150.

After depositing the first gel 150 over the electronic circuit 130, it is to be air-dried at the ambient temperature. The air-drying period may be 10 or 30 minutes, 1, 2, 4, 8 hours, half a day, or more than or equal to one day. After being air-died, the combination of the air dried first gel 150 and the electronic circuit 130 may be peeled off from the substrate 120.

The air-dried hydrogel or the first gel 150, however, is not suitable for directly usages because air-dried hydrogels are unstable due to high solubility in water. In other words, when the air-dried hydrogel is implanted into a plant, animal, or water-related environment, air-dried hydrogels are likely soluble in the water. To make the air-dried hydrogel insoluble in water, the first gel 150 is to be chemically or physically crosslinked.

To stabilize the air-dried first gel 150, a second gel 170 may be deposited over the air-dried first gel 150. The second gel 170 may cover a portion of the air-dried first gel 150. The deposition may be performed by a syringe 160 with a needle. In an instance, the computing device 105 may display specific instruction how the syringe 160 is used to deposit the second gel 170. In another instance, deposition of the second gel 170 may be performed by the inkjet head 110 based on instructions from the computing device 105.

The covered portion of the air-dried first gel 150 by the second gel 170 is physically cross-linked. The non-crosslinked portion of the air-dried first gel 150 may be partially redissolved.

The second gel 170 may be made of the same or different components as those of the first gel 150. The second gel 170 goes through a freeze-thaw method to physically crosslink the air-dried first gel 150 to form a hybrid gel, hybrid cryogel, or simply cryogel. The freeze-thaw method includes a freezing process, which freezes the second gel 170 and the air-dried first gel 150, and a thawing process, which thaws the frozen second gel 170 and air-dried first gel 150. The freezing process may be performed at minus 20 degree Celsius (° C.) for about 20 minutes, and the thawing process may be performed at the room temperature for 10 minutes. The freezing temperature may be greater than or less than −20° C. based on the freezing point of the gels 150, 170, and the freezing period may be greater than or less than 20 minutes if the first and second gels 150, 170 become frozen during the freezing period. Likewise, the thawing temperature may be less than or great than the room temperature as far as it is greater than the freezing point, and the thawing period may be greater than or less than 20 minutes if the frozen gels are thawed during the thawing period. In an aspect, the freeze-thaw process may be performed more than one time. For example, the freeze-thaw process may be repetitively performed 2, 3, 4, 5, or more than 5 times.

In an aspect, to physically crosslink the first and second gels 150, 170, ultraviolet (UV) light may be used. When the UV light is to cure the second gel 170, the UV light may be used to crosslink the first and second gels 150, 170 so that the crosslinked first and second gels are not easily dissolved in water.

After the freeze-thaw process or UV curing, the final result is a gel-electronic circuit 100, which is peeled off from the substrate 120. After the gel-electronic circuit 100 is peeled off from the substrate 120, the crosslinked first and second gels become the substrate or the baseplate of the gel-electronic circuit 100. Also, the crosslinked first and second gels have a conductivity up to 350 Scm⁻¹ and a high transconductance in vivo in the mS range.

The gel-electronic circuit 100 may be a resistor, capacitor, inductor, or transistor. In an aspect, the gel-electronic circuit 100 may be implemented three-dimensionally. For example, after the first gel 150 is deposited over the first electronic circuit, another electronic circuit may be deposited thereover, and another first gel 150 may be deposited over the second electronic circuit. The first electronic circuit and the second circuit may be connected via one or more vias. Such vias may be made by puncturing a hole through the first gels 150 and depositing the conductive materials through the holes. In this way, multiple layers of electronic circuits may be included in the gel-electronic circuit 100. The freeze-thaw process may be performed at the last step or after each first gel 150 is deposited.

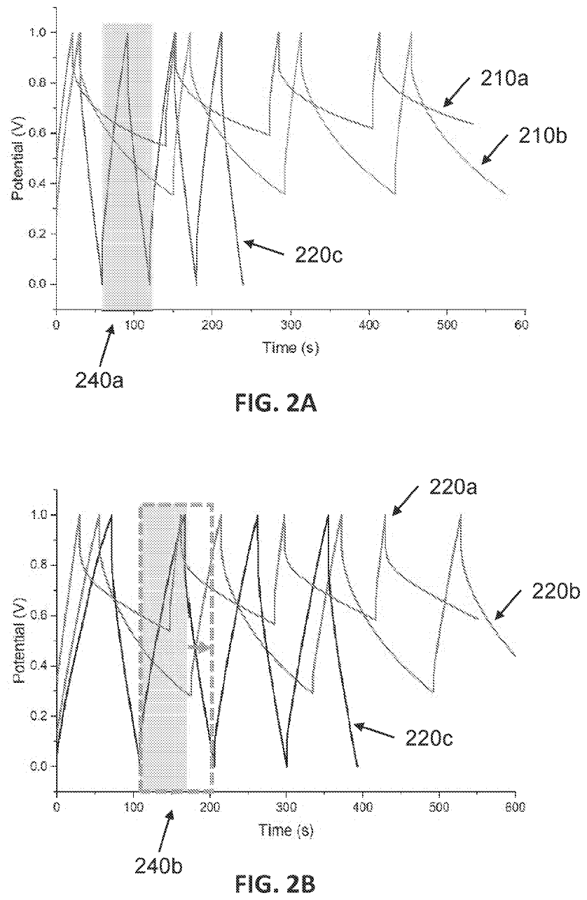

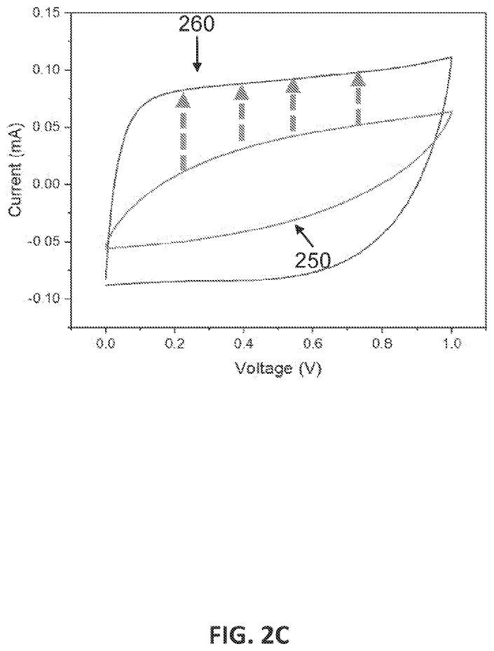

During the freeze-thaw process, the first gel 150 and the second gel 170 are physically crosslinked so that the physically crosslinked combined gels or freeze-thawed cryogels have various features. For example, FIGS. 2A and 2B illustrate charging and discharging patterns of an air-dried hydrogel capacitor and a freeze-thawed cryogel capacitor, respectively. Within an applied voltage window ranging from 0 to 10 V, curves 210a-210c are obtained from the air-dried hydrogel capacitor at different current densities, 1, 10, and 100 μA, respectively, and curves 220a-220c are obtained from a cryogel capacitor at different current densities, 1, 10, and 100 μA, respectively.

In particular, a time window 240a shows a charging and discharging period, during which the air-dried hydrogel capacitor charges and discharges with 10 μA, and is about 60 or 70 seconds. On the other hand, a time window 240b shows a charging and discharging period, during which the freeze-thawed cryogel capacitor charges and discharges with 10 μA, and is about 100 seconds. Thus, the time window 240b for the freeze-thawed cryogel capacitor is increased about 40 to 50% from the time window 240a for the air-dried hydrogel capacitor. Likewise, a time window of about 180 seconds for the freeze-thawed cryogel capacitor with 1 μA is increased from a time window of about 150 seconds for the air-dried hydrogel, and a time window of about 160 seconds for the freeze-thawed cryogel capacitor with 100 μA is increased from a time window of about 140 seconds for the air-dried hydrogel. Thus, by increasing the time window for charging and discharging, the freeze-thawed cryogel capacitor shows changes in electrical characteristics from the air-dried hydrogel capacitor.

Now turning to FIG. 2C, illustrated is cyclic voltammetry cycles within an applied voltage window ranging from 0 to 10 V to the air-dried hydrogel capacitor and the freeze-thawed cryogel capacitor. In particular, curve 250 shows a cyclic voltammetry cycle of the air-dried hydrogel capacitor and curve 260 shows a cyclic voltammetry cycle of the freeze-thawed cryogel capacitor. Based on the curve 250, as the voltage is increased from 0 V to 1 V, the Amperes measured at the air-dried hydrogel capacitor are also increased slowly from −0.05 mV to +0.05 mV, and as the voltage is dropped from 1 V to 0 V, the Amperes measured at the air-dried hydrogel capacitor are also dropped slowly from +0.05 mV to −0.05 mV. On the other hand, based on the curve 260, as the voltage is increased from 0.0 V to 1.0 V, the Amperes measured at the freeze-thawed cryogel capacitor stay at about −0.8 mA until the voltage reaches at about 0.6 V and are exponentially increased from about −0.8 mA to +0.8 mA from 0.6 V, and as the voltage is dropped from 1.0 V to 0.0 V, the Amperes measured at the freeze-thawed cryogel stays at about 1.0 mA or are slowly decreased until the voltage is decreased by about 0.2 V and are exponentially decreased from about +0.8 mA to −0.8 mA from 0.2 V to 0.0 V.

Capacitors generally have two separate conductors or conductive traces. On the substrate 120, the conductive materials may be deposited linearly to form a capacitor. In an aspect, the conductive materials may be deposited in a wave shape or spring shape so that the length of facing two separate conductive traces can be increased to have a more capacitance value than that of two separate linear conductive traces. Further, the spring-shaped trace such as serpentine shapes or fractal-inspired features may withstand greater mechanical deformation/applied stress. In an aspect, the capacitance of the freeze-thawed cryogel capacitor may be high in specific capacitive structures up to 4.2 mF·g⁻¹.

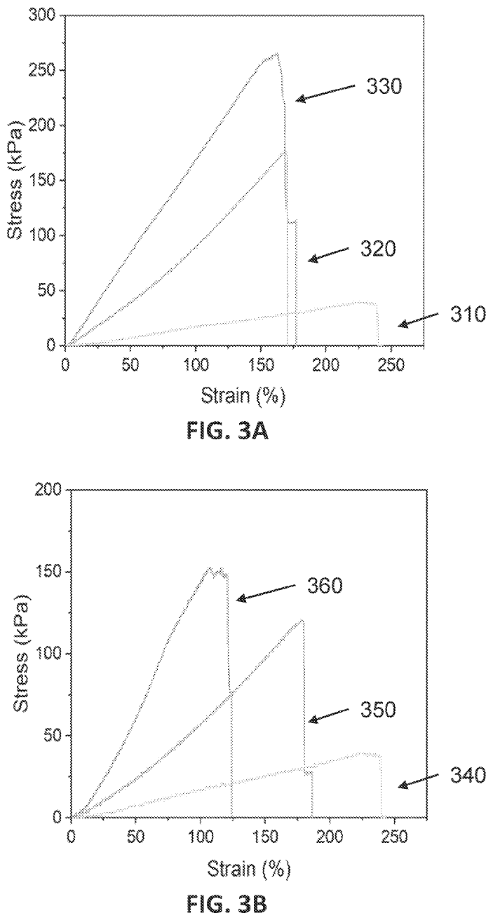

In aspects, the freeze-thawed cryogels may increase mechanical performance based on the number and the duration of the freeze-thaw processes compared to the air-dried hydrogel. For example, air-dried PVA gels display a high Young modulus, which is a ratio of stress to strain, in the hundreds of kPa range. In this regard, with reference to FIGS. 3A and 3B, stress-strain curves 310-360 show stress levels in kPa with respect to stretchability. The stress-strain curve 310 is obtained after the freeze-thawed process has been performed once, the stress-strain curve 320 is obtained after the freeze-thawed process has been performed three times, and the stress-strain curve 330 is obtained after the freeze-thawed process is performed five times.

The freeze-thawed cryogels with one time of the freeze-thawed process can be deformed about 230% with stress force less than 50 kPa based on the stress-strain curve 310, meaning that the freeze-thawed cryogels with one time freeze-thawed process is weak in response to a small stress. On the other hand, based on the stress-strain curves 320 and 330, the freeze-thawed cryogels with three or five times of the freeze-thawed process show substantially high resistance to deformation. For example, with stress force about 150 kPa, the freeze-thawed cryogels with three times of the freeze-thawed process can be deformed only about 170% or 180%. The freeze-thawed cryogels with five times of the freeze-thawed processes can withstand the deformation about 170% with stress force of about 250 kPa. Thus, to obtain desired resistance to deformation, an appropriate number of the freeze-thawed processes may be estimated or calculated based on this trend of stress-strain curves 310-330.

Now, turning back to FIG. 3B, stress-strain curves 340-360 show stress levels in kPa with respect to stretchability based on a time duration of the freeze-thawed process. Specifically, durations of the freeze-thawed process for the stress-strain curves 340-360 are 30 minutes, 4 hours, and 24 hours, respectively. For example, with regard to 30 minutes of the freeze-thawed process, 20 minutes of freezing and 10 minutes of thawing may be performed. In an aspect, the ratio between the freezing time and the thawing time may be adjusted to obtain a suitable stress-strain ratio.

When compared the stress-strain curves 340-360 with each other, the longer the freeze-thawed process time is, the better the resistance to deformation is. Thus, by controlling the freeze-thawed process time, a required or desired stress-strain ratio may be obtained for cryogels.

In an aspect, the freeze-thawed cryogels can be stretched or elongated with stress based on the molecular weight or percentage of the hybrid gel. For example, increasing the molecular weight or the percentage of the cryogel increases the stretchability limits of the freeze-thawed cryogel up to 330%.

Thus, by utilizing three methods, which include 1) controlling the number of the freeze-thawed process, 2) controlling the freeze-thawed process time, and 3) controlling the molecular weight or the percentage of the cryogels, good mechanical properties of Young's modulus in the kPa range may be maintained or obtained.

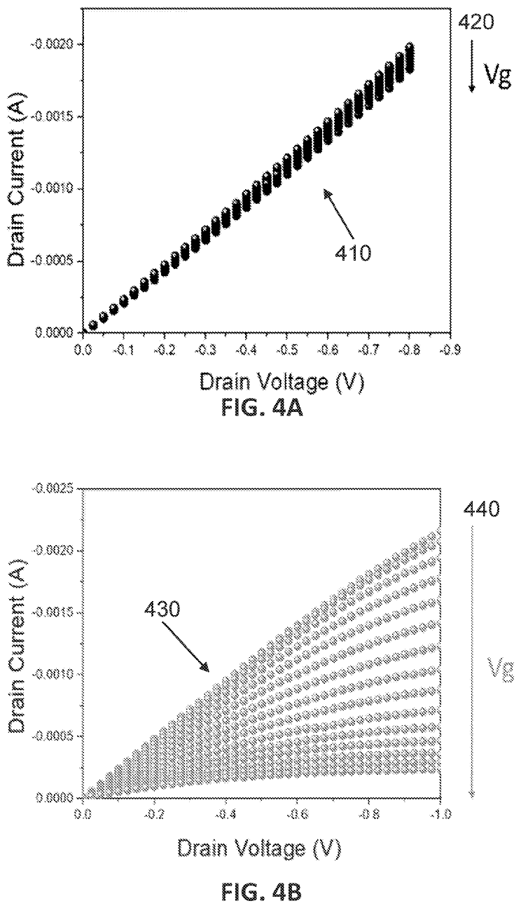

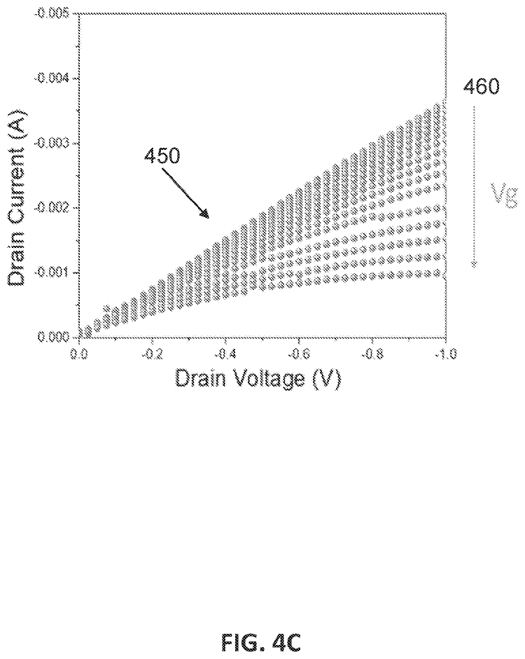

Now reference to FIG. 4A, illustrated are data plots 410 of drain current of an organic electrochemical transistor (OECT), which is air-dried. For example, the gel-electronic circuit 100 of FIG. 1, which is covered with the first gel 150 after air-drying is an air-dried OECT. Downward arrow 420 indicates that a gate voltage V_{g} of the air-dried OECT increases as the downward arrow 420 goes down. The length of the downward arrow 420 is shown short, meaning that the changes in the gate voltage V_{g}, which is applied to the gate terminal (e.g., the gate terminal 132 of FIG. 1), do not significantly affect the drain current i_{d} and the drain voltage V_{d} measured at the drain terminal (e.g., one of the terminals 134 and 136 of FIG. 1). Thus, the drain current is i_{d} more affected by the drain voltage V_{d} rather than by the gate voltage V_{g}. The relationship between the drain current i_{d} and the drain voltage V_{d} appears to be linear, meaning that the air-dried OECT has a relatively constant transconductance. The transconductance at the drain terminal can be obtained by a ratio of a change in current to a change at the drain terminal in voltage. The transconductance of the air-dried OECT may be about 2 or 3 mS.

Contrast to the air-dried OECT of FIG. 4A, the data plot 430 of FIG. 4B shows that the drain current is affected by the gate voltage Vg. The data plot 430 is obtained from an air-dried OECT with an ionic gel. The gate terminal is separated from the source and drain terminal or there is a gap between the gate terminal and the channel, and the ionic gel is injected into or doped into the gap. The ionic gel may have cations or anions, and may be electrolyte or, for example, a methylcellulose-based ionic gel.

When the gate voltage V_{g} is low, the drain current is about −2 mA at the drain voltage V_{d} at −1.0 V, and, when the gate voltage V_{g} is high, the drain current is about −0.2 mA at the drain voltage V_{d} at −1.0 V. Thus, transconductance of the air-dried OECT with the ionic gel changes its conductance from about 2 mS at the low gate voltage V_{g} to 0.2 mS.

Now turning to FIG. 4C, the data plot 450 shows that the drain current is affected by the gate voltage V_{g}. The data plot 450 is obtained from a freeze-thawed (FT) OECT with an ionic gel. When the gate voltage V_{g} is low, the drain current is about −3.5 mA at the drain voltage V_{d} at −1.0 V, and, when the gate voltage V_{g} is high, the drain current is about −0.8 mA at the drain voltage V_{d} at −1.0 V. Thus, transconductance of the freeze-thawed OECT with the ionic gel changes its conductance from about 3.5 mS at the low gate voltage V_{g} to about 0.8 mS. Thus, the freeze-thawed OECT with the ionic gel provides more current at the drain terminal with a higher conductance than the other two OECTs.

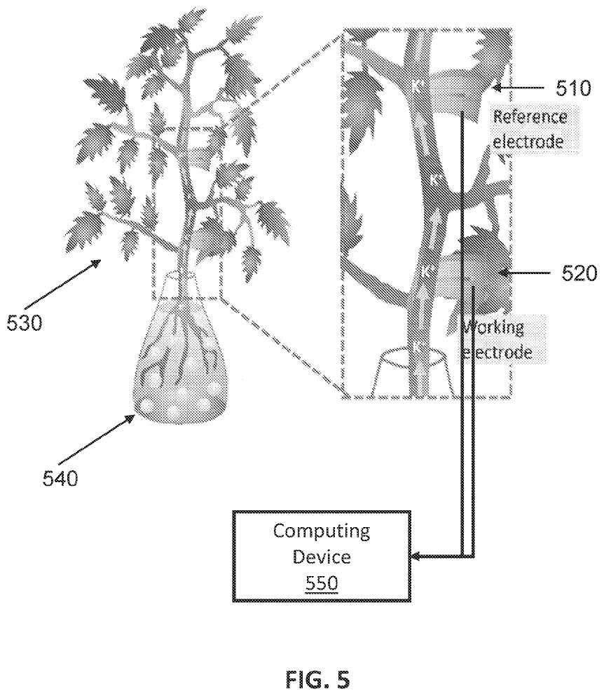

Hydrogels and cryogels are biocompatible so that they can be used in aqueous environments such as within plants, animals, or aqueous solutions. In other words, cryogel electronic circuits may be implanted into aqueous environment to monitor statues of the aqueous environment. For example, to understand plant physiology and the movement of ions into sap, FIG. 5 illustrates cryogel electronic circuits implanted into a plant 530 for monitoring a health status of the plant according to embodiments of the present disclosure.

Cryogel electronic circuits 510 and 520 are a reference electrode and a working electrode, respectively, and are connected to a computing device 550 via wires. In an aspect, the cryogel electronic circuits 510 and 520 may be connected to a monitoring device, which receives signals from the cryogel electronic circuit 510 and 520 and wirelessly transmits the monitored signals to the computing device 550. In this instance, the computing device 550 may process the monitored signals and provide a health status based on the processed signals, which may be displayed on a display screen of the computing device 550. In this way, users may be able to be notified of the health status of the plant 530. In an aspect, the computing device 550 may communicate with the cryogel electronic circuits 510 and 520, wirelessly.

The cryogel electronic circuits 510 and 520 may be implanted to the xylem and phloem of the plant 530 because the xylem and phloem provide flow passageways for water and nutrients. The nutrients may be dissolved in the water 540 in ionic form. For example, K+ or Na+ are dissolved in the water 540. As the ions flow between the cryogel electronic circuits 510 and 520, such flows generate potential (i.e., voltage) and current.

In an aspect, the cryogel electronic circuits 510 and 520 may be a reference electrode and a working electrode, respectively. While the ions flow between the cryogel electronic circuits 510 and 520, potential may be generated and current flows between the cryogel electronic circuits 510 and 520. Based on the signal sensed by the reference electrode 510 as a reference, the voltage and current are measured at the working electrode 520.

In another aspect, the cryogel electronic circuits 510 and 520 may be an OECT, which includes two parts: one is a gate and the other one is a channel including a source and a drain. The cryogel electronic circuits 510 and 520 may be the gate and the channel, respectively, or the other way around. Based on the gap between the gate 510 and the channel 520, the sensitivity of the OECT may be affected. The gap may be 5.7 cm, 9.5 cm, or 15 cm. This list of distances is provided as examples and is not limited to such.

The cryogel electronic circuits 510 and 520 may be implanted along the water passageway. One of them is positioned in the downstream and the other one is positioned in the upstream in a healthy stem to identify a pattern of healthy stem so that patterns of signal obtained later may be compared with the healthy pattern to find out changes in the health status of the plant. In particular, in response to a pattern of voltages applied to the gate 510, a pattern of drain current and voltage is measured. The computing device 550 may receive and process the pattern of voltages applied to the gate 510 and the pattern of drain current and voltage, generate a plurality of profiles based on the circumstances, receive the current measurements, and identify the current health status of the plant 530 by comparing the current measurements with the plurality of profiles.

With regard to the processing of the signals, the computing device 550 may employ a Fourier transformation and/or inverse Fourier transformation to convert the time domain signals to frequency domain signals or vice versa. In this instance, the computing device 550 may perform impedance spectroscopy to analyze impedance over a frequency range from 22 Hz to 200 kHz. In an aspect, variation of impedance may be compared at a fixed frequency, for example, 995 Hz.

Monitoring electrical signals in stems enables the detection of physiological changes due to hydration, nutritional uptake and plant stress. The plant 530 in the growth phase has a high consumption of nutrients, especially potassium and nitrate ions. Nutrient consumption may be evaluated through flow modulation on potassium uptake by roots. To evaluate the nutrient uptake of the stems, cryogel electronic circuits 510 and 520 are implanted in the stem of the plant 530.

To create the plurality of profiles, controlled experiments are needed to be performed. For example, after implantation, the plant roots are first kept in the tap water for a predetermined number of days (e.g., 7 days), the impedance of the stem in water remains stable over this period of time. After the predetermined period, the tap water is replaced with growing fluid including a solution of KCl.

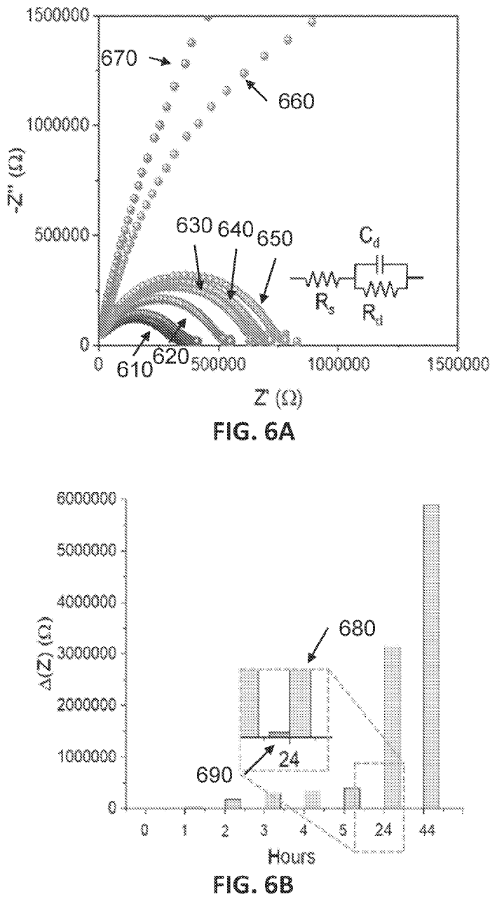

To further understand characteristics of the signals, the plant 530 may be modeled as a circuit having a first resistor in series with a second resistor and a capacitor in parallel. Using this model, the first resistor may be considered the sum of contact and bulk solution resistance, Rs, the second resistor in parallel with the capacitor may be considered as charge transfer resistance in the double layer, Rd, and the capacitor may be considered the double layer capacitance of the electrodes, Cd, as illustrated in FIG. 6A.

After about 40 minutes of soaking in KCl, both Rs and Rd decrease. Together, these could be interpreted as the electrodes experiencing an environment of higher salinity. Rs decreases as ion concentrations and ionic conductivity in the xylem and phloem increase. By Le Chatelier's principle, an increase in cations in the plant tissue may help reduce the energy required and rate of reaction for this process to happen. While performing these types of control experiments where the stem is moved from a water container to a second water container with ions of nutrients, current and voltage signals are monitored to generate a plurality of profiles. These profiles may be impedance spectroscopy or, in particular, may be generated at a fixed frequency, 995 Hz.

As example for the profiles, another controlled experiment may be made to generate a profile of a dying plant due to lack of water. In consideration of this model of the circuit having the first resistor in series with the second resistor and a capacitor in parallel, Nyquist plots 610-670 are also illustrated in FIG. 6A. In this controlled experiment, the plant 530 is left in a drought condition for 44 hours and impedance spectroscopy is performed to generate data at 1 hour, 2 hours, 3 hours, 4 hours, 5 hours, 26 hours, and 44 hours. The data is processed to generate the Nyquist plots 610-670 at 1 hour, 2 hours, 3 hours, 4 hours, 5 hours, 26 hours, and 44 hours, respectively, after applying the draught condition. The horizontal axis represents a real part of the impedance, and the vertical axis represents an imaginary part of the impedance. Based on the trends in the Nyquist plots 610-650, the real and imaginary parts of the impedance slowly increase as the drought condition maintained during the first 5 hours.

At 26 hours after the draught condition, however, the imaginary part of the impedance increases substantially based on the Nyquist plot 660, and at 44 hours, the imaginary part of the impedance further increases. Thus, based on the Nyquist plot, the health status related to the draught condition may be identified.

FIG. 6B shows bar graphs 680 and 690 of electrochemical impedance measured by a gel-electronic circuit implanted in a plant without the draught condition and with the draught condition, respectively. The horizontal axis represents time and the vertical axis represents variation of the electrochemical impedance. The bar graphs around the 24^{th} hour are expanded to show the bar graph 690 because the bar graph 690 is relatively small compared to the bar graph 680. In other words, the variation of the electrochemical impedance without the draught condition is comparatively small, about +/−5 kΩ, compared to the variation of the electrochemical impedance, about +3140 kΩ, with the draught condition. Further, the bar graph 680 shows an increasing trend in the variation of the electrochemical impedance. After 24 hours, the increase in the variation of the electrochemical impedance is substantially larger than the variation of the electrochemical impedance before 24 hours. Thus, when the variation of the electrochemical impedance becomes abruptly large, it is reasonable to assume that the plant is experiencing the draught condition.

Based on the Nyquist plot and/or the bar graph of the variation of the electrochemical impedance, the health status of the plant may be identified. Likewise, when profiles for each health status are collected/generated/found, current health status of the plant may be identified by finding the best profile based on current measurements.

In this regard, a machine learning algorithm may be trained to generate and identify profiles for each health status based on training data, which includes tagged information.

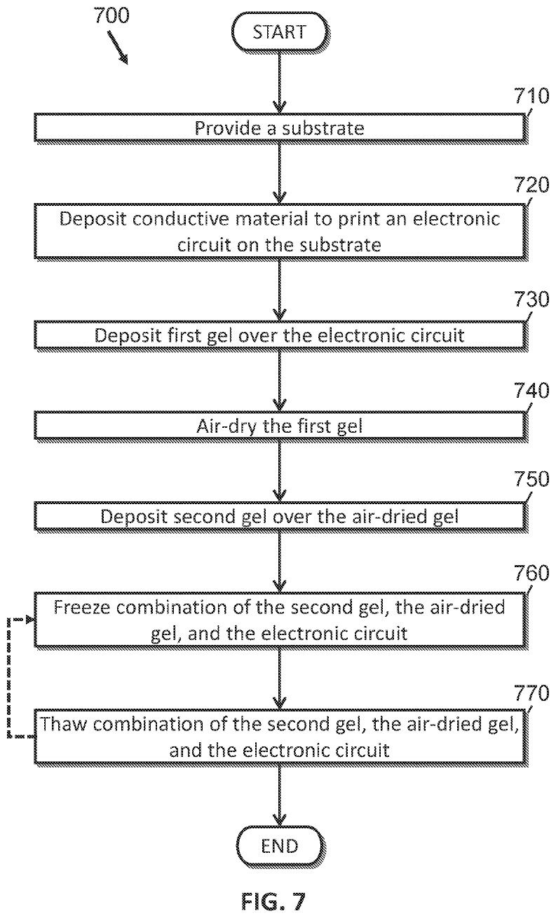

Now turning to FIG. 7, illustrated is a flowchart of a method 700 for fabricating a gel-electronic circuit. For example, the gel-electronic circuit may be the gel-electronic circuit 100 of FIG. 1. The gel-electronic circuit may exhibit features suitable for implanting into a plant, animal, or water-related environment to monitor the status of the object. Since hydrogels and cryogels are bio-compatible, the gel-electronic circuits may be better suited to monitor statuses than metal-based circuits because the metal-based circuits can be corroded within the aqueous environment.

In step 710, a substrate is provided. The substrate may be silicon or glass substrate. On the substrate, conductive material is deposited to print an electronic circuit in step 720. The electronic circuit may be a resistor, inductor, capacitor, transistor, or any combination thereof. Deposition of the conductive material may be performed by an inkjet head of an inkjet printer. Since the deposition is performed on the substrate, the electronic circuit is all planar, and thus each trace of the electronic circuit is also planar or linear. The width of each trace may be dependent upon the resolution of the inkjet head. Based on the real estate on the substrate, one or more electronic circuits may be deposited on the substrate and each of them may be connected so that a combination of the electronic circuits forms a complex circuit.

The conductive material may include conductive polymer composite comprising citric acid and cyclodextrin, PVA covalently crosslinked by glutaraldehyde (GA), and conducting polymer (e.g., PEDOT:PSS) to fabricate self-adhesive films for electromyography. PEDOT:PSS may be in aqueous inks whose rheological properties are compatible with low-cost printing processes (such as inkjet and screen printing). This conductive polymer may be used as conductive traces in countless printed flexible electronic devices for biomedical applications as well as for agricultural applications. In an aspect, the conducting polymer may be successively cured on a conventional hot plate at 90° C. under ambient conditions.

After the electronic circuit is cured, a first gel is deposited over the electronic circuit in step 730. The deposition of the first gel may be done by drop-casting the first gel by using a syringe with a needle or by the inkjet head. The first gel may be a hydrogel, which is made of PVA, PHEMA, PAAm, PEGDA, Sodium alginate, PVA, PEO, PVP, MAA, NIPAAm, PEGMA, HPMC, PEG, CMC, Chitosan, HA, PAA, PHPMA, Polysaccharide-based hydrogels, PEO-PPO-PEO, PEGDMA, PNVP, PVA-VAc, PMAA-EGDMA, PEO-DEAEMA, Sodium polyacrylate, PAA-HEMA, Agarose, NIPAAm-AAc, and/or PAM-AMPS. This list of chemical compounds is provided as examples and may include other chemical compounds for the hydrogel. In an aspect, PVA-based gels may be prepared by dissolving different ratios between deionized water and PVA weight, for example, 100:5, 100:10, or 100:20. The PVA may have different molecular weights, for example, 31,000-50,000, 89,000-98,000, or 146,000-186,000. The PVA powder may be dissolved in deionized water at 90° C. using magnetic stirring to create the hydrogels or the first gel.

Hydrogels are self-healable. The self-healing capabilities are linked to the number of hydroxyl groups in the hydrogels. For example, the self-healing ability of the PVA cryogel depends on the formation of hydrogen bonding between PVA chains. The self-healing capabilities of the polymer are linked to the number of hydroxyl groups of vinyl alcohol. Thus, increasing the crosslinking between the chains reduces the possibility of recreating hydrogen bonding between PVA chains. Reconnecting the electronic cryogels after a cut may be challenging as it requires precise alignment. Further, the resistance of the trace may change after the reconnection. For example, when the thickness of the printed conducting layer is in the micron range while the substrate thickness is on the order of 175 μm, the resistance of the trace after reuniting the two cut parts together increases from 9 kΩ up to 13 kΩ (ratio 1.5) after 15 min of self-healing. Nevertheless, due to the self-healing properties, hydrogels may be used to mimic functionalities of human skin.

Further, hydrogels are stretchable and biocompatible. Thus, the hydrogels may be implantable in stems of plants or inside the human or animal skin.

The hydrogels or first gels are air-dried on the substrate in step 740. After the air-drying process is complete, the air-dried gel with the electronic circuit may be peeled off from the substrate. One of shortcomings by air-drying the first gel is that air-dried hydrogels are easily dissolved in water. Thus, air-dried hydrogels may not be directly implanted into aqueous environment due to their solubility in water.

To overcome this shortcoming, a second gel is deposited over the air-dried first gel in step 750. The second gel may cover only a portion of the first gel and does not cover the other portions of the first gel. The covering portion may cover the electronic circuit other than its terminal portion, The deposition of the second gel may be done by drop-casting the second gel by using a syringe with a needle or by the inkjet head. The second gel may have the same compositions as the first gel.

While the first gel is air-dried, the second gel is cured by freezing in step 760 and thawing in step 770. The freeze-thawed gels are not easily soluble in the water. While freezing and thawing process, the first gel may be physically interlinked with the second gel so as to form a hybrid gel, hybrid cryogel, or simply cryogel. The freezing process at step 760 may be performed at −20° C. for about 20 minutes, and the thawing process at step 770 may be performed at the room temperature for 10 minutes. The freezing temperature may be greater than or less than −20° C. based on the freezing point of each gel and the freezing period may be greater than or less than 20 minutes if the first and second gels become frozen during the freezing period. Likewise, the thawing temperature may be less than or great than the room temperature as far as it is greater than the freezing point, and the thawing period may be greater than or less than 20 minutes if the frozen gels are thawed during the thawing period.

In an aspect, the freeze-thaw process may be performed more than one time. For example, the freeze-thaw process may be repetitively performed 2, 3, 4, 5, or more than 5 times. Since the freeze-thaw process changes electrical and physical properties of the cryogels, the number of repetitions of the freeze-thaw process may be predetermined to meet requirements of the finalized cryogel electronic circuit.

In another aspect, the duration of each of the freezing process and the thawing process also affect its electrical and physical properties of the cryogels, the duration of each of the freezing process and the thawing process may be predetermined to meet requirements of the finalized cryogel electronic circuit.

The physical properties may include a stretchability or Young's modulus, which can be controlled by the molecular weight of percentage of the cryogels. Self-healing is another physical property that the hydrogels and cryogels are able to reconnect when they are cut and when the cut portions are placed close to each other.

When the freeze-thawed cryogel circuit is a capacitor, the electrical properties may include a charging and discharging period and a specific capacitive value. In a case where the freeze-thawed cryogel circuit is a transistor or OCET, the electrical properties may include a change in the drain current and voltage as the gate voltage increases.

After the freeze-thaw process, the final product or the freeze-thawed cryogel electronic circuit may be completely peeled off from the substrate. The freeze-thawed cryogel may work as a substrate for the electronic circuit.

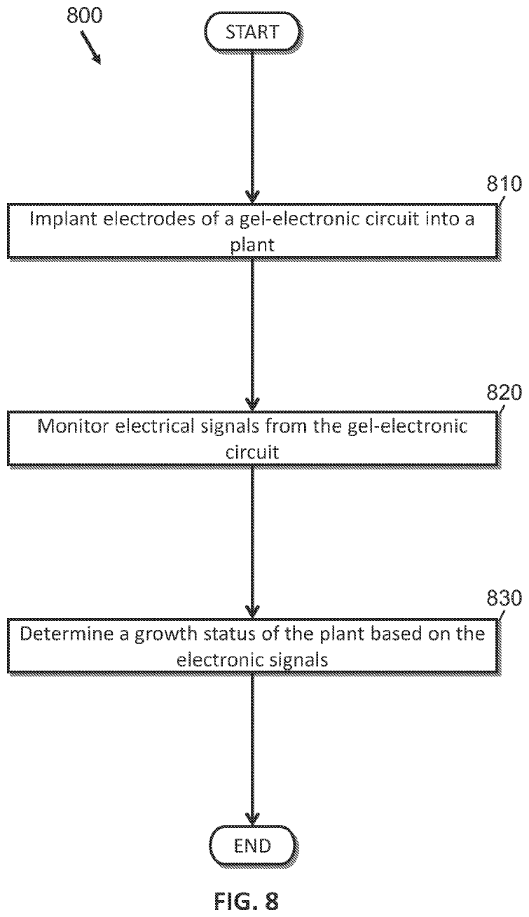

Now turning to FIG. 8, illustrated is a method 800 for monitoring a grow status of a plant with implanted gel-electronic circuit. Due to the biocompatible properties of hydrogels and cryogels, the freeze-thawed cryogel electronic circuit may be implanted into a plant in step 810. Further, the electronic circuit is covered by the hydrogels or cryogels, there is no corrosion, while metal-based implant circuits have such corrosion problem in an aqueous environment.

The implanted cryogel electronic circuit monitors electrical signals within the plant in step 820. The electrical signals are sensed by two electrodes of the freeze-thawed cryogel electronic circuit. The two electrodes include a reference electrode and a working electrode. Based on the distance between the working and reference electrodes, amplitude of the electrical signals may be affected. Thus, the distance between the two electrodes may be controlled to capture sufficiently large electrical signals.

In an aspect, the implanted cryogel electronic circuit may be a transistor, which can amplify the amplitude of the electrical signal. The transistor may be the OECT (e.g., the transistor 130 of FIG. 1), which includes a gate and a channel having a drain and a source. Since the gate and the channel are separated by a gap, the gate and the channel may be implanted into the plant and separated by a distance corresponding to the gap. By applying periodic voltage signals to the gate, corresponding results in the drain may be monitored. Water flowing with ions can be reflected in the electrical signals. Thus, when the water level within the plant decreases, the corresponding pattern may be identified as an increase in the electrochemical impedance in the drain. Likewise, increase in ions in the water flow can be expressed in a higher current or a lower electrochemical impedance in the drain.

By processing the electrical signals and comparing them with predetermined profiles, a growth status or health status of the plant may be determined in step 830. The predetermined profiles may be generated after controlled experimentations. For example, a draught condition is applied to one plant and a normal condition is applied to another plant, and respective results are compared to each other to find a profile for the draught condition.

The processing of the electrical signals may involve transformation between the time space and the frequency space and electrochemical impedance analysis at a range of frequencies (e.g., 22 Hz to 200 kHz) or at a specific frequency (e.g., 995 Hz). This range of frequencies and the specific frequency are provided as examples and can be differently set based on the type of plant, location of the cryogel electronic circuit, and any readily appreciated factors.

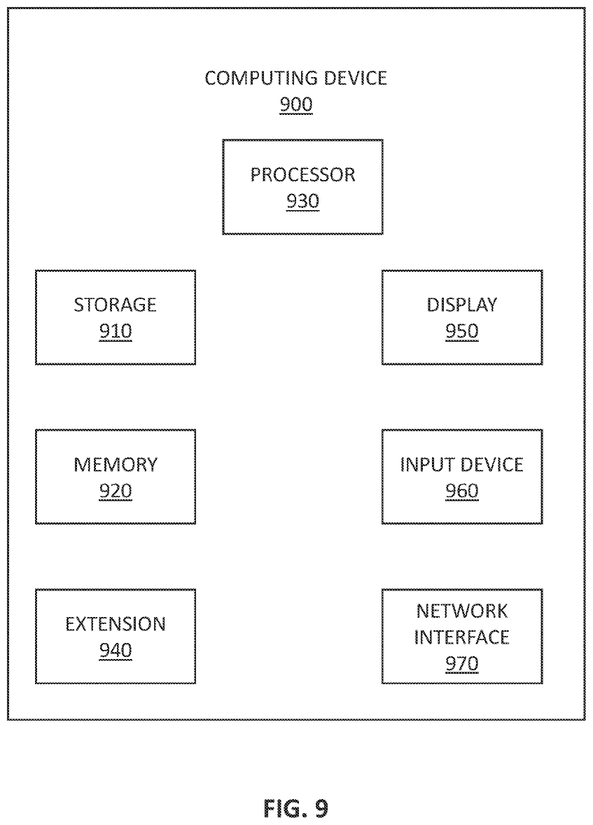

Attention will now be directed to FIG. 9, which illustrates a computing device 900 representative of the computing device 105 of FIG. 1, the computing device 550 of FIG. 5, or any computing modules, units, and devices described herein. The computing device 900 may include, by way of non-limiting examples, server computers, cloud computers, desktop computers, laptop computers, notebook computers, sub-notebook computers, netbook computers, netpad computers, set-top computers, handheld computers, Internet appliances, mobile smartphones, tablet computers, personal digital assistants, video game consoles, embedded computers, smart watches, smart sensors, or other devices capable of performing calculations/operations. Those of skill in the art will recognize that many smartphones are suitable for use in the system described herein. Suitable tablet computers include those with booklet, slate, and convertible configurations, known to those of skill in the art.

The computing device 900 includes an operating system configured to perform executable instructions. The operating system is, for example, software, including programs and data, which manages the device's hardware and provides services for execution of applications. Those of skill in the art will recognize that suitable server operating systems include, by way of non-limiting examples, FreeBSD, OpenBSD, NetBSD®, Linux, Apple® Mac OS X Server®, Oracle® Solaris®, Windows Server®, and Novell® NetWare®. Those of skill in the art will recognize that suitable personal computer operating systems include, by way of non-limiting examples, Microsoft® Windows®, Apple® Mac OS X®, UNIX®, and UNIX-like operating systems such as GNU/Linux®. In some embodiments, the operating system is provided by cloud computing. Those of skill in the art will also recognize that suitable mobile smart phone operating systems include, by way of non-limiting examples, Nokia® Symbian® OS, Apple® iOS®, Research In Motion® BlackBerry OS®, Google® Android®, Microsoft® Windows Phone® OS, Microsoft® Windows Mobile® OS, Linux®, and Palm® WebOS®.

In some embodiments, the computing device 900 may include a storage 910 and a memory 920. The storage 910 is one or more physical apparatus used to store data or programs on a temporary or permanent basis. In some embodiments, the storage 910 may be volatile memory and requires power to maintain stored information. In some embodiments, the storage 910 includes, by way of non-limiting examples, CD-ROMs, DVDs, flash memory devices, magnetic disk drives, magnetic tape drives, optical disk drives, and cloud computing-based storage. In some embodiments, the memory 920 may be non-volatile memory and retains stored information when the computing device 900 is not powered. In some embodiments, the non-volatile memory includes flash memory. In some embodiments, the non-volatile memory includes dynamic random-access memory (DRAM). In some embodiments, the non-volatile memory includes ferroelectric random-access memory (FRAM). In some embodiments, the non-volatile memory includes phase-change random access memory (PRAM). In some embodiments, the storage 910 and the memory 920 may be a combination of devices such as those disclosed herein.

The storage 910 includes executable instructions (i.e., compiled codes or machine codes). The executable instructions represent instructions that are executable by the processor 930 of the computing device 900 to perform the disclosed operations, such as those described in the various methods. Furthermore, the storage 910 excludes data, carrier waves, and propagating data. On the other hand, the storage 910 that carries computer-executable instructions may be “transmission media” and include data, carrier waves, and propagating data. Thus, by way of example and not limitation, the current embodiments may include at least two distinctly different kinds of computer-readable media: computer storage media and transmission media.

The computing device 900 further includes a processor 930, an extension 940, a display 950, an input device 960, and a network card 970. The processor 930 is a brain to the computing device 900. The processor 930 executes instructions which implement tasks or functions of programs. When a user executes a program, the processor 930 reads the program stored in the storage 910, loads the program on the RAM, and executes instructions prescribed by the program.

The processor 930 may include, without limitation, Field-Programmable Gate Arrays (“FPGA”), Program-Specific or Application-Specific Integrated Circuits (“ASIC”), Program-Specific Standard Products (“ASSP”), System-On-A-Chip Systems (“SOC”), Complex Programmable Logic Devices (“CPLD”), Central Processing Units (“CPU”), Graphical Processing Units (“GPU”), or any other type of programmable hardware by performing the basic arithmetic, logical, control and input/output (I/O) operations specified by the instructions. As used herein, terms such as “executable module,” “executable component,” “component,” “module,” or “engine” may refer to the processor 930 or to software objects, routines, or methods that may be executed by the processor 930 of the computing device 900. The different components, modules, engines, and services described herein may be implemented as objects or the processor 930 that executes on the computing device 900 (e.g., as separate threads).

In embodiments, the extension 940 may include several ports, such as one or more universal serial buses (USBs), IEEE 1394 ports, parallel ports, and/or expansion slots such as peripheral component interconnect (PCI) and PCI express (PCIe). The extension 940 is not limited to the list but may include other slots or ports that may be used for appropriate purposes. The extension 940 may be used to install hardware or add additional functionalities to a computer that may facilitate the purposes of the computer. For example, a USB port may be used for adding additional storage to the computer and/or an IEEE 1394 may be used for receiving a large amount of data (e.g., measurement data from freeze-thawed cryogel electronic circuits (e.g., electrodes 510 and 520, or OECTs) for an extended period of time (e.g., 120 days).

In some embodiments, the display 950 may be a cathode ray tube (CRT), a liquid crystal display (LCD), or light emitting diode (LED). In some embodiments, the display 950 may be a thin film transistor liquid crystal display (TFT-LCD). In some embodiments, the display 950 may be an organic light emitting diode (OLED) display. In various some embodiments, the OLED display is a passive-matrix OLED (PMOLED) or active-matrix OLED (AMOLED) display. In some embodiments, the display 950 may be a plasma display. In some embodiments, the display 950 may be a video projector. In some embodiments, the display may be interactive (e.g., having a touch screen or a sensor such as a camera, a 3D sensor, a LiDAR, a radar, etc.) that may detect user interactions/gestures/responses and the like.

A user may input and/or modify data via the input device 960 that may include a keyboard, a mouse, or any other device with which the user may input data. The display 950 displays data on a screen of the display 950. The display 950 may be a touch screen so that the display 950 may be used as an input device.

The network card 970 is used to communicate with other computing devices, wirelessly or via a wired connection. Through the network card 970, one or more data links and/or data switches that enable the transport of electronic data between computer systems, modules, and/or other electronic devices. When information is transferred, or provided, over a network (either hardwired, wireless, or a combination of hardwired and wireless) to a computer, the computer properly views the connection as a transmission medium. The computing device 900 may include one or more communication channels that are used to communicate via the network card 970. Data or desired program codes are carried or transmitted in the form of computer-executable instructions or in the form of data structures via the network card 970.

The embodiments disclosed herein are examples of the disclosure and may be embodied in various forms. For instance, although certain embodiments herein are described as separate embodiments, each of the embodiments herein may be combined with one or more of the other embodiments herein. Specific structural and functional details disclosed herein are not to be interpreted as limiting, but as a basis for the claims and as a representative basis for teaching one skilled in the art to variously employ the present disclosure in virtually any appropriately detailed structure.

Any of the herein described methods, programs, algorithms, or codes may be converted to or expressed in one or more programming languages or computer programs. The terms “programming language” and “computer program,” as used herein, each include any language used to specify instructions to a computer, and include (but is not limited to) the following languages and their derivatives: Assembler, Basic, Batch files, BCPL, C, C+, C++, C#, Delphi, Fortran, Java, JavaScript, machine code, operating system command languages, Pascal, Perl, PL1, scripting languages, Visual Basic, meta-languages which themselves specify programs, and all first, second, third, fourth, fifth, or further generation computer languages. Also included are database and other data schemas, and any other meta-languages. No distinction is made between languages which are interpreted, compiled, or use both compiled and interpreted approaches. No distinction is made between compiled and source versions of a program. Thus, reference to a program, where the programming language could exist in more than one state (such as source, compiled, object, or linked) is a reference to any and all such states. Reference to a program may encompass the actual instructions and/or the intent of those instructions.

It should be understood that various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (e.g., all described acts or events may not be necessary to carry out the techniques). In addition, while certain aspects of this disclosure are described as being performed by a single module or unit for purposes of clarity, it should be understood that the techniques of this disclosure may be performed by a combination of units or modules.

The present invention may be embodied in other specific forms without departing from its characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method for fabricating a printed gel-electronic circuit, the method comprising:
depositing a conductive material on a substrate;
depositing first gel over the conductive material on the substrate;
air-drying the first gel;
depositing second gel over the air-dried gel;
freezing a combination of the second gel, the air-dried gel, and the conductive material; and
thawing the combination of the second gel, the air-dried gel, and the conductive material.

2. The method according to claim 1, wherein the conductive material is ejected through a nozzle of inkjet printer.

3. The method according to claim 1, wherein freezing and thawing steps are performed more than one time.

4. The method according to claim 1, wherein the second gel is deposited over a portion of the air-dried first gel.

5. The method according to claim 1, wherein the conductive material forms an electrode, a capacitor, a transistor, or any combination thereof.

6. The method according to claim 1, wherein a width of each trace of the conductive material is greater than or equal to 100 micrometers.

7. The method according to claim 1, wherein the first gel is hydrogel.

8. The method according to claim 1, wherein the second gel is cryogel.

9. The method according to claim 1, wherein the first gel and the second gel are biocompatible and made of polyvinyl alcohol (PVA), Poly(2-hydroxyethyl methacrylate) (PHEMA), Polyacrylamide (PAAm), Polyethylene glycol diacrylate (PEGDA), Sodium alginate, Polyvinyl alcohol (PVA), Polyethylene oxide (PEO), Polyvinylpyrrolidone (PVP), Methacrylic acid (MAA), N-isopropylacrylamide (NIPAAm), Poly(ethylene glycol) methacrylate (PEGMA), Hydroxypropyl methylcellulose (HPMC), Polyethylene glycol (PEG), Gelatin, Carboxymethyl cellulose (CMC), Chitosan, Sodium hyaluronate (HA), Polyacrylic acid (PAA), Poly(2-hydroxypropyl methacrylate) (PHPMA), Polysaccharide-based hydrogels, Poly(ethylene oxide)-poly(propylene oxide) poly(ethylene oxide) triblock copolymers (PEO-PPO-PEO), Poly(ethylene glycol) dimethacrylate (PEGDMA), Poly(N-vinyl-2-pyrrolidone) (PNVP), Poly(vinyl alcohol-co-vinyl acetate) (PVA-VAc), Poly(methacrylic acid-co-ethylene glycol dimethacrylate) (PMAA-EGDMA), Poly(ethylene oxide-co-2-(diethylamino)ethyl methacrylate) (PEO-DEAEMA), Sodium polyacrylate, Poly(acrylic acid co 2 hydroxyethyl methacrylate) (PAA-HEMA), Agarose, Poly(N isopropylacrylamide-co-acrylic acid) (NIPAAm-AAc), and/or Poly(acrylamide co-2-acrylamido-2-methylpropanesulfonic acid) (PAM-AMPS).

10. The method according to claim 1, wherein the freezing the combination is performed at a temperature less than or equal to −20° C. and for at least 30 minutes.

11. A gel-electronic circuit fabricated by a freeze-thaw process, the gel-electronic circuit comprising:
an electronic circuit, which has been formed by a conductive material and includes at least two terminals;
a first gel covering the electronic circuit and being air-dried; and
a second gel covering the first gel and being freeze-thawed.

12. The gel-electronic circuit according to claim 11, wherein the gel-electronic circuit is stretchable, and
wherein the gel-electronic circuit has a self-healing property based on hydroxyl groups in the first and second gels.

13. The gel-electronic circuit according to claim 11, wherein the second gel is deposited over a portion of the air-dried first gel.

14. The gel-electronic circuit according to claim 11, wherein the electronic circuit includes an electrode, a capacitor, a transistor, or any combination thereof.

15. The gel-electronic circuit according to claim 14, wherein a transconductance of the transistor is in a milli-Siemens range, and a capacitance of the capacitor is less than or equal to 4.2 millifarad.

16. The gel-electronic circuit according to claim 11, wherein a width of each trace of the electronic circuit is greater than or equal to 100 micrometers.

17. The gel-electronic circuit according to claim 14, wherein a conductivity of each trace is less than or equal to 350 Siemens/cm.

18. The gel-electronic circuit according to claim 11, wherein the first gel and the second gel are biocompatible and made of polyvinyl alcohol (PVA), Poly(2-hydroxyethyl methacrylate) (PHEMA), Polyacrylamide (PAAm), Polyethylene glycol diacrylate (PEGDA), Sodium alginate, Polyvinyl alcohol (PVA), Polyethylene oxide (PEO), Polyvinylpyrrolidone (PVP), Methacrylic acid (MAA), N-isopropylacrylamide (NIPAAm), Poly(ethylene glycol) methacrylate (PEGMA), Hydroxypropyl methylcellulose (HPMC), Polyethylene glycol (PEG), Gelatin, Carboxymethyl cellulose (CMC), Chitosan, Sodium hyaluronate (HA), Polyacrylic acid (PAA), Poly(2-hydroxypropyl methacrylate) (PHPMA), Polysaccharide-based hydrogels, Poly(ethylene oxide)-poly(propylene oxide) poly(ethylene oxide) triblock copolymers (PEO-PPO-PEO), Poly(ethylene glycol) dimethacrylate (PEGDMA), Poly(N-vinyl-2-pyrrolidone) (PNVP), Poly(vinyl alcohol-co-vinyl acetate) (PVA-VAc), Poly(methacrylic acid-co-ethylene glycol dimethacrylate) (PMAA-EGDMA), Poly(ethylene oxide-co-2-(diethylamino)ethyl methacrylate) (PEO-DEAEMA), Sodium polyacrylate, Poly(acrylic acid co 2 hydroxyethyl methacrylate) (PAA-HEMA), Agarose, Poly(N isopropylacrylamide-co-acrylic acid) (NIPAAm-AAc), and/or Poly(acrylamide co-2-acrylamido-2-methylpropanesulfonic acid) (PAM-AMPS).

19. A method for monitoring an electrochemical status of an object by using a gel-electronic circuit fabricated by a freeze-thaw process, the method comprising:
implanting electrodes of the gel-electronic circuit into a portion of an object;
monitoring electrical signals from the gel-electronic circuit for a period of time based on ion movements through the object; and
determining an electrochemical status of the object by comparing the monitored electrical signals with a plurality of predetermined signal profiles.

20. The method according to claim 19, wherein the period is greater than or equal to 120 days without corroding the electrodes.
